(19) United States
(12) Patent Application Publication
(10) Pub. No.: US 2022/0068999 A1
(43) Pub. Date: Mar. 3, 2022

(54) MICRO-LED DISPLAY DEVICE AND MANUFACTURING METHOD OF THE SAME

(71) Applicant: PlayNitride Display Co., Ltd., Zhunan Township (TW)

(72) Inventors: Yu-Hung LAI, Zhunan Township (TW); Yung-Chi CHU, Zhunan Township (TW)

(73) Assignee: PlayNitride Display Co., Ltd., Zhunan Township (TW)

(21) Appl. No.: 17/029,279

(22) Filed: Sep. 23, 2020

(30) Foreign Application Priority Data
Aug. 31, 2020 (TW) 109129714

(51) Int. Cl. H01L 27/15; H01L 33/62; H01L 33/56; H01L 33/00

(52) U.S. Cl. CPC H01L 27/156; H01L 33/62; H01L 2933/0066; H01L 33/0093; H01L 2933/005; H01L 33/56

(57) ABSTRACT

A micro-LED display device is provided. The micro-LED display device includes a substrate having a first circuit layer and a second circuit layer. The micro-LED display device also includes a first pad and a second pad respectively disposed on the first circuit layer and the second circuit layer. The micro-LED display device further includes a micro-LED that includes a first electrode and a second electrode. The first electrode and the second electrode are respectively connected to the first pad and the second pad. Moreover, the micro-LED display device includes a first bonding support layer disposed between the first pad and the second pad and in direct contact with the substrate and the micro-LED. The tensile stress of the first bonding support layer is greater than or equal to 18 MPa.

### CROSS REFERENCE TO RELATED APPLICATIONS

This application claims priority of Taiwan Patent Application No. 109129714, filed on Aug. 31, 2020, the entirety of which is incorporated by reference herein.

### BACKGROUND

### Technical Field

Embodiments of the present disclosure relate in general to a micro-LED display device and a manufacturing method of the same, and in particular they relate to a micro-LED display device that includes a bonding support layer and a manufacturing method of the same.

### Description of the Related Art

A light-emitting diode (LED) display is an active semiconductor device display with such advantages as low power consumption, excellent contrast, and better visibility in sunlight. With the development of portable electronic devices and the increasing demands from users for higher display quality such as better color and contrast, micro-LED displays made of light-emitting diodes arranged in arrays have gradually attracted attention in the market.

Nowadays, there are still some challenges in the production of micro-LED display devices for micro-LED displays. For example, when manufacturing a micro-LED display device, it is necessary to pick up a plurality of micro-LEDs from a carrier substrate and transfer them to a receiving substrate, and then the micro-LEDs are firmly set on the receiving substrate through bonding, curing and other processes.

However, when the micro-LEDs are transferred to the receiving substrate, they are prone to skew. Moreover, since each micro-LED has a small volume and little overall thickness, cracks can easily be generated between its two electrodes during the bonding process. Furthermore, the distance between the electrodes is small, so that the pads on the receiving substrate for connecting the electrodes can easily contact each other during the bonding and/or curing process, causing a short circuit.

Therefore, although the existing micro-LED display devices generally meet the requirements, there are still some problems. How to improve upon existing micro-LED display devices has become one of the issues to which the industry attaches great importance.

### SUMMARY

Embodiments of the present disclosure relate to a micro-LED display device that includes a bonding support layer and a manufacturing method of the same. By forming the bonding support layer between the pads for connecting the electrodes of the micro-LED, it may effectively prevent the pads from contacting each other during the bonding and/or curing process and causing a short circuit. Moreover, the bonding support layer may be used as a reference when the micro-LED is transferred to the receiving substrate to prevent the micro-LED from being skew. Furthermore, the bonding support layer is in direct contact with the micro-LED during the bonding process and curing process, which may be used to support the micro-LED and prevent the micro-LED from cracking, and the micro-LED may be more firmly bonded to the substrate.

Some embodiments of the present disclosure include a micro-LED display device. The micro-LED display device includes a substrate having a first circuit layer and a second circuit layer. The micro-LED display device also includes a first pad and a second pad respectively disposed on the first circuit layer and the second circuit layer. The micro-LED display device further includes a micro-LED that includes a first electrode and a second electrode. The first electrode and the second electrode are respectively connected to the first pad and the second pad. Moreover, the micro-LED display device includes a first bonding support layer disposed between the first pad and the second pad and in direct contact with the substrate and the micro-LED. The tensile stress of the first bonding support layer is greater than or equal to 18 MPa.

Some embodiments of the present disclosure include a manufacturing method of a micro-LED display device. The manufacturing method includes providing a substrate, and the substrate has a first circuit layer and a second circuit layer. The manufacturing method also includes forming a first pad and a second pad respectively on the first circuit layer and the second circuit layer. The manufacturing method further includes forming a bonding support material on the substrate, the first pad and the second pad. Moreover, the manufacturing method includes patterning the bonding support material to form a first bonding support layer between the first pad and the second pad. The tensile stress of the first bonding support layer is greater than or equal to 18 MPa. The manufacturing method also includes connecting a carrier substrate having a micro-LED with the substrate. The micro-LED includes a first electrode and a second electrode. The manufacturing method further includes performing a bonding process to make the first bonding support layer bond the substrate and the micro-LED. The first electrode and the second electrode are respectively connected to the first pad and the second pad. Furthermore, the manufacturing method includes removing the carrier substrate.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-2B are cross-sectional views illustrating various stages of manufacturing the micro-LED display device according to one embodiment of the present disclosure.

FIGS. 3-4B are cross-sectional views illustrating various stages of manufacturing the micro-LED display device according to another embodiment of the present disclosure.

FIG. 5 is a cross-sectional view illustrating the micro-LED display device according to one embodiment of the present disclosure.

FIG. 6 is a cross-sectional view illustrating the micro-LED display device according to one embodiment of the present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

In the following, according to some embodiments of the present disclosure, a micro-LED display device that includes a bonding support layer and a manufacturing method thereof are proposed. By forming the bonding support layer between the pads for connecting the electrodes of the micro-LED, it may effectively prevent the pads from causing a short circuit and prevent the micro-LED from being skew. It may also be used to support the micro-LED and prevent the micro-LED from cracking, and the micro-LED may be more firmly bonded to the substrate.

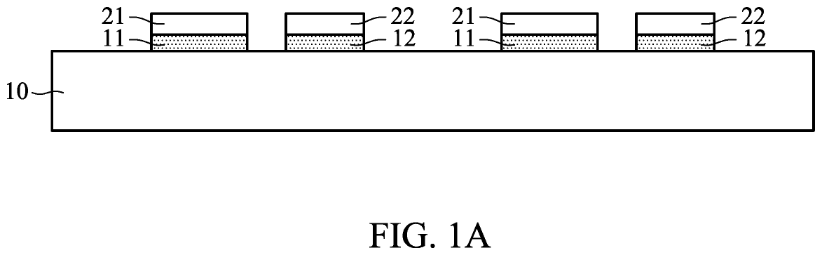

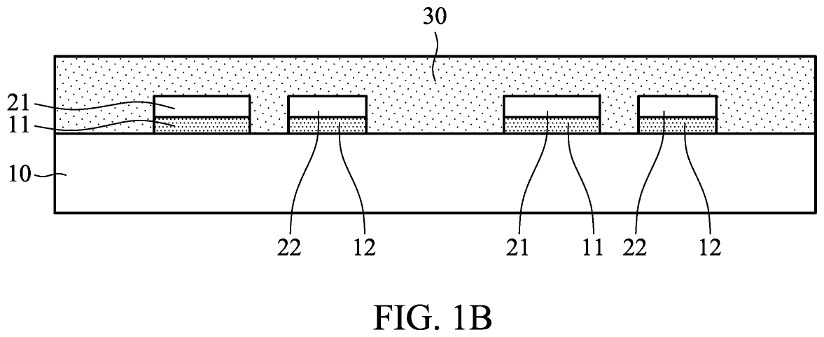

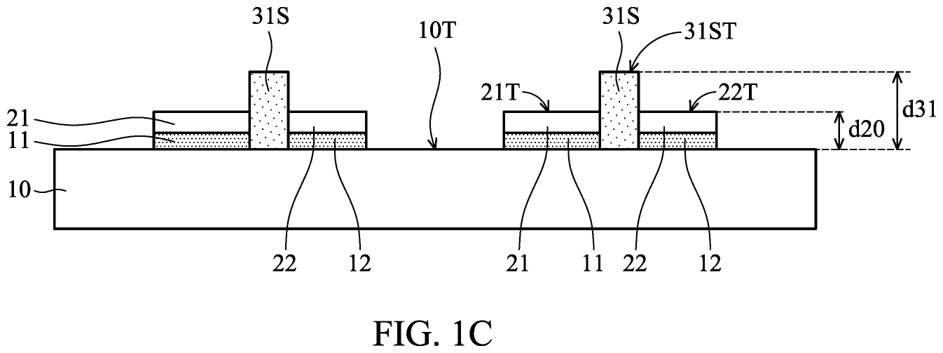

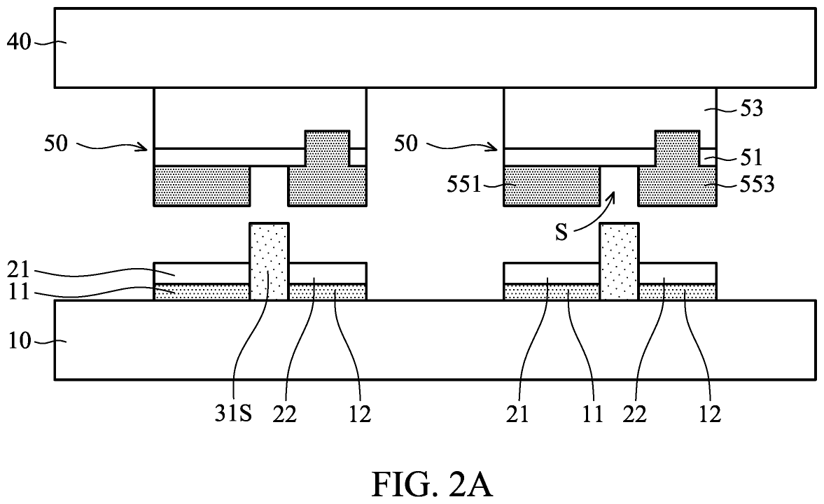

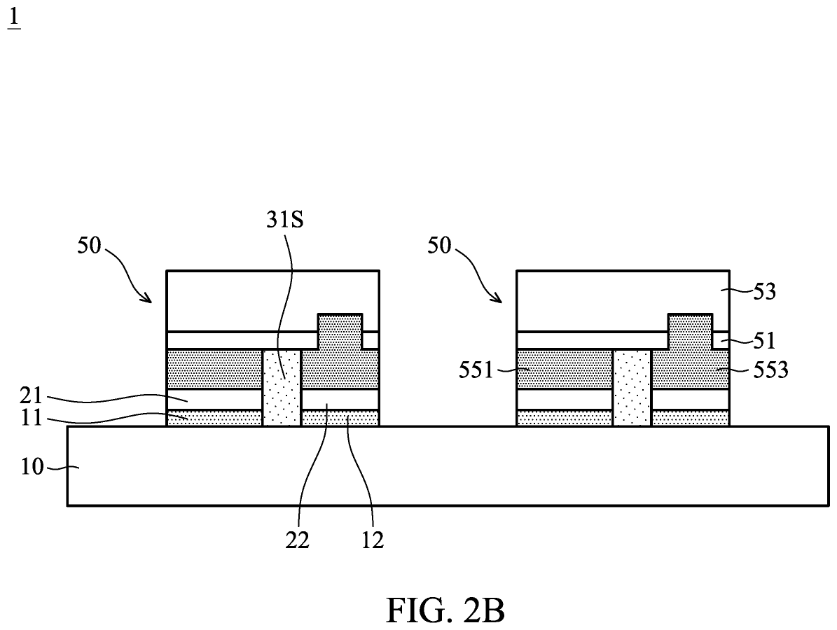

FIGS. 1A-2B are cross-sectional views illustrating various stages of manufacturing the micro-LED display device 1 according to one embodiment of the present disclosure. It should be noted that some components may be omitted in FIGS. 1A-2B for sake of brevity.

Referring to FIG. 1A, a substrate 10 is provided. In some embodiments, the substrate 10 may be, for example, a display substrate, a light-emitting substrate, a substrate with functional elements such as thin-film transistors (TFT) or integrated circuits (IC), or other types of circuit substrates, but the present disclosure is not limited thereto. For example, the substrate 10 may be a bulk semiconductor substrate or include a composite substrate formed of different materials, and the substrate 10 may be doped (e.g., using p-type or n-type dopants) or undoped. In some embodiments, the substrate 10 may include a semiconductor substrate, a glass substrate, or a ceramic substrate, such as a silicon substrate, a silicon germanium substrate, a silicon carbide substrate, an aluminum nitride substrate, a sapphire substrate, the like, or a combination thereof, but the present disclosure is not limited thereto. In some embodiments, the substrate 10 may include a semiconductor-on-insulator (SOI) substrate formed by disposing a semiconductor material on an insulating layer, but the present disclosure is not limited thereto.

In some embodiments, the substrate 10 may have a first circuit layer 11 and a second circuit layer 12. As shown in FIG. 1A, the substrate 10 has a plurality of first circuit layers 11 and a plurality of second circuit layers 12, and the first circuit layers 11 and the second circuit layers 12 may respectively form circuit arrays. It should be noted that the number of first circuit layers 11 and second circuit layers 12 is not limited to the figures of the present disclosure, and may be adjusted according to actual requirements (e.g., the number of micro-LEDs 50).

Then, referring to FIG. 1A, a first pad 21 and a second pad 22 are respectively formed on the first circuit layer 11 and the second circuit layer 12. The first pad 21 and the second pad 22 may be used to bond the electrodes of the micro-LED 50 (see the following figures) to electrically connect the micro-LED 50 to the substrate 10. The material of the first pad 21 and the second pad 22 may include metal, conductive polymer, or metal oxide. For example, the material of the first pad 21 and the second pad 22 may include indium (In), but the present disclosure is not limited thereto. In some embodiments, the first pad 21 and the second pad 22 may be formed by physical vapor deposition (PVD), chemical vapor deposition (CVD), atomic layer deposition (ALD), evaporation, sputtering, the like, or a combination thereof, but the present disclosure is not limited thereto.

Referring to FIG. 1B, a bonding support material 30 is formed on the substrate 10, the first pad 21 and the second pad 22. In particular, the bonding support material 30 is formed on the substrate 10, fills the space between the first pads 21 and the second pads 22 (and/or between the first circuit layers 11 and the second circuit layers 12), and covers the first pads 21 and the second pads 22. In some embodiments, the bonding support material 30 may include a polymer material, such as benzocyclobutene (BCB), epoxy, acrylic copolymer (e.g., polymethylmethacrylate (PMMA)), and the like, but the present disclosure is not limited thereto. In some embodiments, the bonding support material 30 may include a thermosetting resin, and its glass transition temperature (Tg) may be increased to more than 150° C. by increasing the side chain length or adding functional groups such as cycloalkyl groups. In some embodiments, the glass transition temperature of the bonding support material 30 may be greater than or equal to 190° C. (e.g., between about 190 and about 195° C.), and the Young's modulus of the bonding support material 30 may be between about 1.8 and about 2.2 GPa. In some embodiments, the bonding support material 30 may be formed on the substrate 10, the first pad 21 and the second pad 22 by a deposition process. For example, the deposition process may include spin-on coating, CVD, ALD, the like, or a combination thereof, but the present disclosure is not limited thereto.

Referring to FIG. 1C, the bonding support material 30 is patterned to form a first bonding support layer 31S between the first pad 21 and the second pad 22. Based on the foregoing, the material of the first bonding support layer 31S may include a thermosetting resin, and the glass transition temperature (Tg) of the first bonding support layer 31S may be greater than or equal to 190° C. (e.g., between about 190 and about 195° C.), and the Young's modulus of the first bonding support layer 31S may be between about 1.8 and about 2.2 GPa. In particular, the bonding support material 30 may be patterned by a photolithography process to form the first bonding support layer 31S between the first pad 21 and the second pad 22 (and/or between the first circuit layer 11 and the second circuit layer 12) and expose (the top surface 21T of) the first pad 21 and (the top surface 22T of) the second pad 22. For example, the photolithography process may include photoresist coating (e.g., spin-on coating), soft baking, mask aligning, exposure, post-exposure baking (PEB), developing, rinsing, drying (e.g., hard baking), other suitable processes, or a combination thereof, but the present disclosure is not limited thereto.

As shown in FIG. 1C, in some embodiments, the distance d31 between the top surface 31ST of the first bonding support layer 31S and the top surface 10T of the substrate 10 is greater than the distance d20 between the top surface 21T of the first pad 21 or the top surface 22T of the second pad 22 and the top surface 10T of the substrate 10. That is, the top surface 31ST of the first bonding support layer 31S is higher than the top surface 21T of the first pad 21 or the top surface 22T of the second pad 22 in the normal direction of the top surface 10T of the substrate 10. Therefore, a portion of the first bonding support layer 31S (i.e., the portion of the first bonding support layer 31S higher than the first pad 21 or the second pad 22) may be used to support the micro-LED 50 that is formed later.

Referring to FIG. 2A, a massive transfer process is performed to connect a carrier substrate 40 having a plurality of micro-LEDs 50 with the substrate 10. In some embodiments, the carrier substrate 40 may include a plastic substrate, a glass substrate, a sapphire substrate or other substrates without circuits, but the present disclosure is not limited thereto.

In some embodiments, the micro-LED 50 may include a first-type semiconductor layer 51. In some embodiments, the dopant of the first-type semiconductor layer 51 is N-type. For example, the material of the first-type semiconductor layer 51 includes a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the first-type semiconductor layer 51 may include dopants such as silicon (Si) or germanium (Ge), but the present disclosure is not limited thereto. The first-type semiconductor layer 51 may be a single-layer or multi-layer structure. In some embodiments, the first-type semiconductor layer 51 may be formed by an epitaxial growth process, such as metal organic chemical vapor deposition (MOCVD), hydride vapor phase epitaxy (HVPE), molecular beam epitaxy (MBE), any other applicable method, or a combination thereof, but the present disclosure is not limited thereto.

In some embodiments, the micro-LED 50 may also include a second-type semiconductor layer 53, and the first-type semiconductor layer 51 and the second-type semiconductor layer 53 are stacked with each other. In some embodiments, the dopant of the second-type semiconductor layer 53 is P-type. For example, the material of the second-type semiconductor layer 53 includes a group II-VI material (e.g., zinc selenide (ZnSe)) or a group III-V nitrogen compound material (e.g., gallium nitride (GaN), aluminum nitride (AlN), indium nitride (InN), indium gallium nitride (InGaN), aluminum gallium nitride (AlGaN) or aluminum indium gallium nitride (AlInGaN)), and the second-type semiconductor layer 53 may include dopants such as magnesium (Mg) or carbon (C), but the present disclosure is not limited thereto. The second-type semiconductor layer 53 may be a single-layer or multi-layer structure. Similarly, the second-type semiconductor layer 53 may be formed by an epitaxial growth process. Examples of the epitaxial growth process are described above, and will not be repeated here.

As shown in FIG. 2A, the micro-LED 50 includes a first electrode 551 and a second electrode 553, and the first electrode 551 and the second electrode 553 may be electrically connected to the first-type semiconductor layer 51 and the second-type semiconductor layer 53, respectively. Moreover, the first electrode 551 and the second electrode 553 are separated from each other. That is, there is a space S between the first electrode 551 and the second electrode 553. It should be noted that some components of the micro-LED 50 may be omitted in the figures of the present disclosure for sake of brevity. For example, the micro-LED 50 may include a light-emitting layer (e.g., quantum well (QW) layer), a transparent conductive layer (e.g., indium tin oxide (ITO)), an insulating layer (e.g., silicon oxide (SiOx) or silicon nitride (SiNy)), and the like.

Referring to FIG. 2A and FIG. 2B, a bonding process is performed to make the micro-LED 50 and the corresponding first pad 21 and second pad 22 on the substrate 10 adhere and form electrical connections. Then, the carrier substrate 40 is removed to complete the micro-LED display device 1 according to one embodiment of the present disclosure. In particular, the temperature of the bonding process may be between the glass transition temperature (Tg) and the melting temperature (Tm) of the first bonding support layer 31S, such as between 100 and 300° C., and the bonding time of the bonding process may be between 10 and 60 seconds, but the present disclosure is not limited thereto.

In some embodiments, a curing process may be performed after the bonding process (and before removing the carrier substrate 40). An adhesive force is formed in the contact surface of the first bonding support layer 31S and the micro-LED 50 and the contact surface of the first bonding support layer 31S and the substrate 10 through the curing process, so that the micro-LED 50 may be affixed to the substrate 10. In some embodiments, the first bonding support layers 31 may be used as references when the micro-LEDs 50 are transferred to the substrate 10 to prevent the micro-LEDs 50 from being skew. Moreover, the first bonding support layer 31S is formed between the first pad 21 and the second pad 22, it may effectively prevent the first pad 21 and the second pad 22 from contacting each other during the bonding and/or curing process and causing a short circuit. In particular, the temperature of the curing process may be between 100 and 300° C., and the curing time of the curing process may be between 30 and 120 minutes, but the present disclosure is not limited thereto.

As shown in FIG. 2B, in some embodiments, the first bonding support layer 31S may fill the space S between the first electrode 551 and the second electrode 553 of the micro-LED 50 after performing the bonding process, which may be used to support the micro-LED 50 and prevent the micro-LED 50 from cracking, and the micro-LED 50 may be more firmly bonded to the substrate 10. Therefore, the manufacturing method according to the embodiments of the present disclosure may be suitable for transferring and bonding a huge amount of micro-LEDs 50 to the substrate 10. In other embodiments, the first pad 21 and the second pad 22 may deform and protrude due to the formation of an alloy with the first electrode 551 and/or the second electrode 553 during the bonding and/or curing process. The first bonding support layer 31S may effectively prevent the first pad 21 and the second pad 22 from squeezing out, causing the first pad 21 and the second pad 22 to contact, and forming a short circuit.

As shown in FIG. 2B, in this embodiment, the micro-LED display device 1 includes a substrate 10 having a first circuit layer 11 and a second circuit layer 12. The micro-LED display device 1 also includes a first pad 21 and a second pad 22 respectively disposed on the first circuit layer 11 and the second circuit layer 12. The micro-LED display device 1 further includes a micro-LED 50 that includes a first electrode 551 and a second electrode 553. The first electrode 551 and the second electrode 553 are respectively connected to the first pad 21 and the second pad 22. Moreover, the micro-LED display device 1 includes a first bonding support layer 31S disposed between the first pad 21 and the second pad 22 and in direct contact with the substrate 10 and the micro-LED 50. The tensile stress of the first bonding support layer 31S is greater than or equal to 18 MPa.

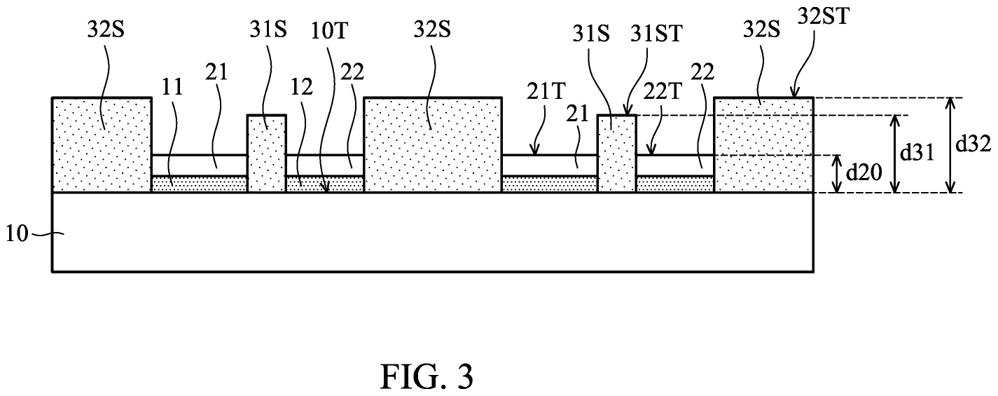

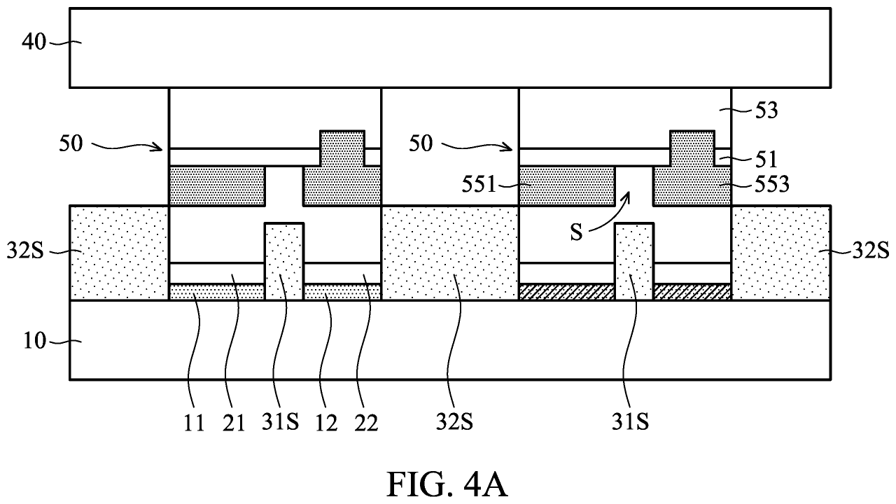

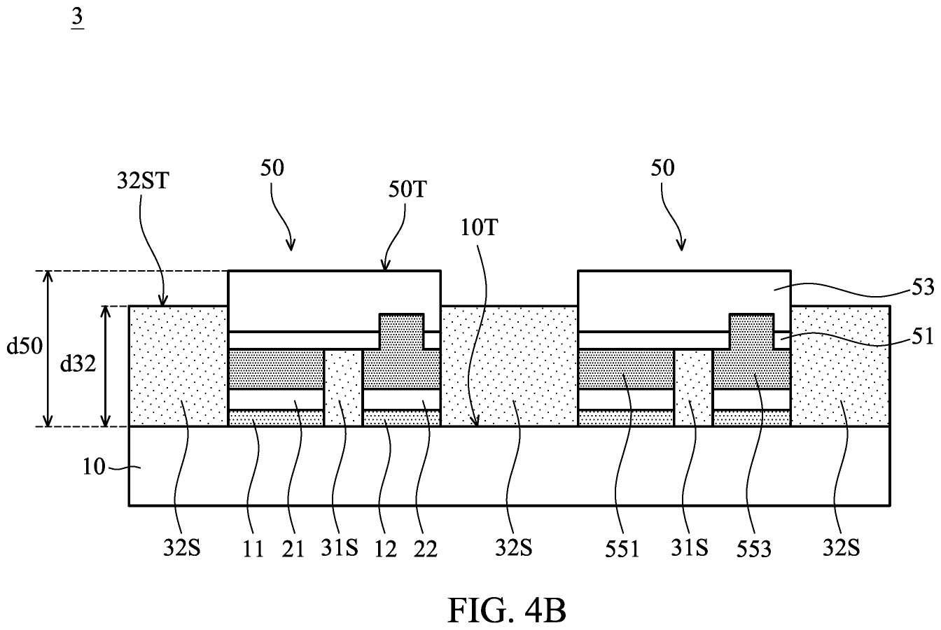

FIGS. 3-4B are cross-sectional views illustrating various stages of manufacturing the micro-LED display device 3 according to another embodiment of the present disclosure. In this embodiment, the stage of manufacturing the micro-LED display device 3 shown in FIG. 3 may be continued after FIG. 1B. Similarly, some components may be omitted in FIGS. 3-4B for sake of brevity.

Referring to FIG. 3, the bonding support material 30 is patterned to form a plurality of first bonding support layers 31S and a plurality of second bonding support layers 32S. The material of the second bonding support layer 32S and the material of the first bonding support layer 31S are the same. For example, the material of the second bonding support layer 32S may include a thermosetting resin, and the glass transition temperature (Tg) of the second bonding support layer 32S may be greater than or equal to 190° C. (e.g., between about 190 and about 195° C.), and the Young's modulus of the second bonding support layer 32S may be between about 1.8 and about 2.2 GPa. In particular, the bonding support material 30 may be patterned by a photolithography process to form the first bonding support layers 31S and the second bonding support layers 32S and expose (the top surface 21T of) the first pad 21 and (the top surface 22T of) the second pad 22. The first bonding support layer 31S is formed in the first pad 21 and the second pad 22 of each of the micro-LEDs 50 and between the first pad 21 and the second pad 22 (and/or between the first circuit layer 11 and the second circuit layer 12); and the second bonding support layers 32S are formed between the first pad 21 and the second pad 22 of two of the adjacent micro-LEDs 50. Examples of the photolithography process are described above, and will not be repeated here.

As shown in FIG. 3, similarly, the distance d31 between the top surface 31ST of the first bonding support layer 31S and the top surface 10T of the substrate 10 is greater than the distance d20 between the top surface 21T of the first pad 21 or the top surface 22T of the second pad 22 and the top surface 10T of the substrate 10. That is, the top surface 31ST of the first bonding support layer 31S is higher than the top surface 21T of the first pad 21 or the top surface 22T of the second pad 22 in the normal direction of the top surface 10T of the substrate 10. Therefore, a portion of the first bonding support layer 31S (i.e., the portion of the first bonding support layer 31S higher than the first pad 21 or the second pad 22) may be used to support the micro-LED 50 that is formed later.

Moreover, in some embodiments, the distance d32 between the top surface 32ST of the second bonding support layer 32S and the top surface 10T of the substrate 10 is greater than the distance d31 between the top surface 31ST of the first bonding support layer 31S and the top surface 10T of the substrate 10. That is, the top surface 32ST of the second bonding support layer 32S is higher than the top surface 31ST of the first bonding support layer 31S in the normal direction of the top surface 10T of the substrate 10, but the present disclosure is not limited thereto. In some other embodiments, the distance d32 between the top surface 32ST of the second bonding support layer 32S and the top surface 10T of the substrate 10 may be equal to the distance d31 between the top surface 31ST of the first bonding support layer 31S and the top surface 10T of the substrate 10. That is, the top surface 32ST of the second bonding support layer 32S and the top surface 31ST of the first bonding support layer 31S may be aligned (coplanar).

Referring to FIG. 4A, a carrier substrate 40 having a plurality of micro-LEDs 50 is connected with the substrate 10. The materials and the structures of the carrier substrate 40 and the micro-LED 50 are as described above, and will not be repeated here. As shown in FIG. 4A, in this embodiment, the first bonding support layer 31S may correspond to the space S between the first electrode 551 and the second electrode 553, and the second bonding support layer 32S may correspond to the space between the micro-LEDs 50.

Referring to FIG. 4B, a bonding process is performed to make the micro-LED 50 and the corresponding first pad 21 and second pad 22 on the substrate 10 adhere and form electrical connections. Then, the carrier substrate 40 is removed to complete the micro-LED display device 3 according to one embodiment of the present disclosure. In some embodiments, a curing process may be performed after the bonding process (and before removing the carrier substrate 40). An adhesive force is formed in the contact surface of the first bonding support layer 31S and the micro-LED 50 and the contact surface of the first bonding support layer 31S and the substrate 10 through the curing process, so that the micro-LED 50 may be affixed to the substrate 10. As shown in FIG. 4B, in this embodiment, the second bonding support layers 32S of the micro-LED display device 3 may be formed between the micro-LEDs 50.

As shown in FIG. 4B, in some embodiments, the distance d32 between the top surface 32ST of each second bonding support layer 32S and the top surface 10T of the substrate 10 is less than the distance d50 between the top surface 50T of each micro-LED 50 and the top surface 10T of the substrate 10. That is, the top surface 32ST of each second bonding support layer 32S is lower than the top surface 50T of each micro-LED 50 in the normal direction of the top surface 10T of the substrate 10, but the present disclosure is not limited thereto. In some other embodiments, the distance d32 between the top surface 32ST of each second bonding support layer 32S and the top surface 10T of the substrate 10 may be equal to the distance d50 between the top surface 50T of each micro-LED 50 and the top surface 10T of the substrate 10. That is, the top surface 32ST of each second bonding support layer 32S and the top surface 50T of each micro-LED 50 may be aligned (coplanar), so that the second bonding support layer 32S may be a flattening layer of the micro-LED display device 3.

Furthermore, the second bonding support layers 32S formed between the micro-LEDs 50 may reduce the crosstalk between different micro micro-LEDs 50 and may make the light emitted from the micro micro-LEDs 50 more concentrated.

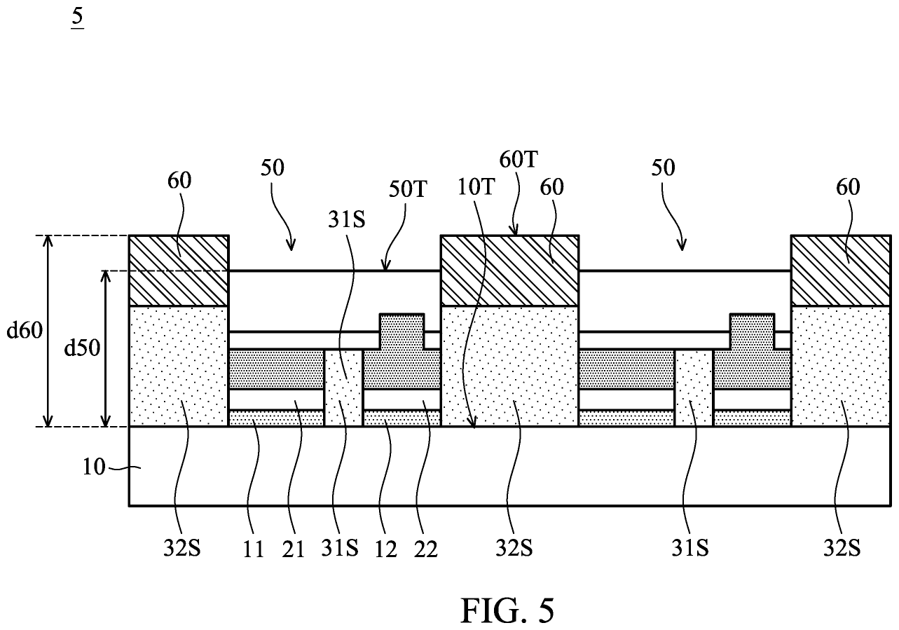

FIG. 5 is a cross-sectional view illustrating the micro-LED display device 5 according to one embodiment of the present disclosure. The micro-LED display device 5 shown in FIG. 5 has a structure similar to that of the micro-LED display device 3 shown in FIG. 4B, and the stage of manufacturing the micro-LED display device 5 shown in FIG. 5 may be continued after FIG. 4B.

Referring to FIG. 5, a plurality of shielding layers 60 are formed on the second bonding support layers 32S. That is, the difference between the micro-LED display device 5 shown in FIG. 5 and the micro-LED display device 3 shown in FIG. 4B is that the micro-LED display device 5 may further include a plurality of shielding layers 60 disposed on the second bonding support layers 32S.

In some embodiments, the material of the shielding layer 60 may include a metal, such as copper (Cu), silver (Ag), and the like, but the present disclosure is not limited thereto. In some other embodiments, the material of the shielding layer 60 may include photoresist (e.g., black photoresist, or any other applicable photoresist which is not transparent), ink (e.g., black ink, or any other applicable ink which is not transparent), molding compound (e.g., black molding compound, or any other applicable molding compound which is not transparent), solder mask (e.g., black solder mask, or any other applicable solder mask which is not transparent), epoxy polymer, any other applicable material, or a combination thereof.

In some embodiments, the shielding layer 60 may be formed on the second bonding support layer 32S through a deposition process, a photolithography process, any other applicable process, or a combination thereof. Examples of the deposition process and the photolithography process are as described above, and will not be repeated here.

In this embodiment, the distance d60 between the top surface 60T of each shielding layer 60 and the top surface 10T of the substrate 10 is greater than the distance d50 between the top surface 50T of each micro-LED 50 and the top surface 10T of the substrate 10. That is, the top surface 60T of each shielding layer 60 is higher than the top surface 50T of each micro-LED 50 in the normal direction of the top surface 10T of the substrate 10, but the present disclosure is not limited thereto. In some other embodiments, the distance d60 between the top surface 60T of each shielding layer 60 and the top surface 10T of the substrate 10 may be equal to the distance d50 between the top surface 50T of each micro-LED 50 and the top surface 10T of the substrate 10. That is, the top surface 60T of each shielding layer 60 and the top surface 50T of each micro-LED 50 may be aligned (coplanar).

Moreover, no matter the top surface 60T of the shielding layer 60 is aligned (coplanar) with the top surface 50T of the micro-LED 50 or higher than the top surface 50T of the micro-LED 50, the shielding layer 60 will expose (at least part of) the top surface 50T of the micro-LED 50. The shielding layer 60 may be used to further prevent crosstalk between different micro-LEDs 50 to improve the light emitting quality of the micro-LED display device 5.

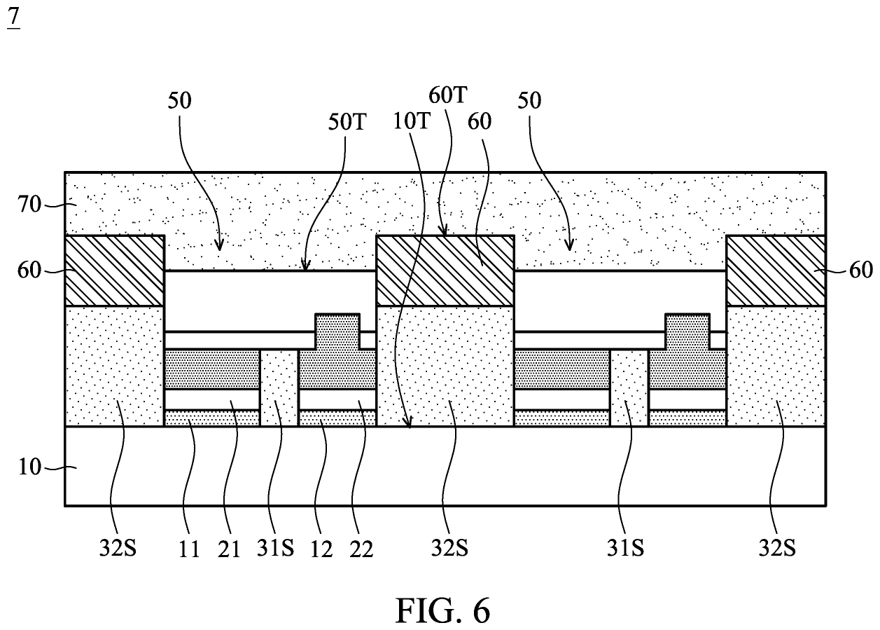

FIG. 6 is a cross-sectional view illustrating the micro-LED display device 7 according to one embodiment of the present disclosure. The micro-LED display device 7 shown in FIG. 6 has a structure similar to that of the micro-LED display device 5 shown in FIG. 5 and the stage of manufacturing the micro-LED display device 7 shown in FIG. 6 may be continued after FIG. 5.

Referring to FIG. 6, an optically clear adhesive (OCA) 70 is formed on the micro-LED 50. That is, the difference between the micro-LED display device 7 shown in FIG. 6 and the micro-LED display device 5 shown in FIG. 5 is that the micro-LED display device 7 may further include an optically clear adhesive 70 disposed on the micro-LED 50. In particular, as shown in FIG. 6, the optically clear adhesive 70 may be disposed on the micro-LED 50 and the shielding layer 60 and in direct contact with the top surface 50T of the micro-LED 50 and/or the top surface 60T of the shielding layer 60.

In some embodiments, the material of the optically clear adhesive 70 may include acrylic resin, but the present disclosure is not limited thereto. In some embodiments, the optically clear adhesive 70 may be formed on the micro-LED 50 by a deposition process (e.g., a spin-on coating process), but the present disclosure is not limited thereto. The optically clear adhesive 70 may reduce glare, increase contrast, avoid Newton's rings, etc., so as to further improve the light-emitting quality of the micro-LED display device 7.

In summary, the micro-LED display device according to the embodiments of the present disclosure includes a bonding support layer formed between the pads for connecting the electrodes of the micro-LED, which may effectively prevent the pads from contacting each other during the bonding process and causing a short circuit. Moreover, the bonding support layer may be used as a reference when the micro-LED is transferred to the receiving substrate to prevent the micro-LED from being skew. Furthermore, the bonding support layer is in direct contact with the micro-LED during the bonding process, the curing process, and the like, which may be used to support the micro-LED and prevent the micro-LED from cracking, and the micro-LED may be more firmly bonded to the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A micro-LED display device, comprising:
a substrate having a first circuit layer and a second circuit layer;
a first pad and a second pad respectively disposed on the first circuit layer and the second circuit layer;
a micro-LED comprising a first electrode and a second electrode that are respectively connected to the first pad and the second pad;
a first bonding support layer disposed between the first pad and the second pad and in direct contact with the substrate and the micro-LED,
wherein a tensile stress of the first bonding support layer is greater than or equal to 18 MPa.

2. The micro-LED display device according to claim 1, wherein the first bonding support layer fills a space between the first electrode and the second electrode.

3. The micro-LED display device according to claim 1, wherein a distance between a top surface of the first bonding support layer and a top surface of the substrate is greater than a distance between a top surface of the first pad or a top surface of the second pad and the top surface of the substrate.

4. The micro-LED display device according to claim 1, wherein a material of the first bonding support layer comprises a thermosetting resin, and a glass transition temperature of the first bonding support layer is greater than or equal to 190° C., and a Young's modulus of the first bonding support layer is between 1.8 and 2.2 GPa.

5. The micro-LED display device according to claim 1, further comprising a plurality of micro-LEDs and a plurality of second bonding support layers, wherein the second bonding support layers are disposed between the micro-LEDs.

6. The micro-LED display device according to claim 5, wherein a top surface of each of the second bonding support layers and a top surface of each of the micro-LEDs are coplanar.

7. The micro-LED display device according to claim 5, wherein a distance between a top surface of each of the second bonding support layers and a top surface of the substrate is less than a distance between a top surface of each of the micro-LEDs and the top surface of the substrate.

8. The micro-LED display device according to claim 7, further comprising:
a plurality of shielding layers disposed on the second bonding support layers.

9. The micro-LED display device according to claim 8, wherein a distance between a top surface of each of the shielding layers and the top surface of the substrate is greater than or equal to a distance between the top surface of each of the micro-LEDs and the top surface of the substrate.

10. The micro-LED display device according to claim 5, wherein a material of each of the second bonding support layers comprises a thermosetting resin.

11. The micro-LED display device according to claim 1, further comprising:
an optically clear adhesive disposed on the micro-LED.

12. A manufacturing method of a micro-LED display device, comprising:
providing a substrate, wherein the substrate has a first circuit layer and a second circuit layer;
forming a first pad and a second pad respectively on the first circuit layer and the second circuit layer;
forming a bonding support material on the substrate, the first pad and the second pad;
patterning the bonding support material to form a first bonding support layer between the first pad and the second pad, wherein a tensile stress of the first bonding support layer is greater than or equal to 18 MPa;
connecting a carrier substrate having a micro-LED with the substrate, wherein the micro-LED comprises a first electrode and a second electrode;
performing a bonding process to make the first bonding support layer bond the substrate and the micro-LED, wherein the first electrode and the second electrode are respectively connected to the first pad and the second pad; and
removing the carrier substrate.

13. The manufacturing method of the micro-LED display device according to claim 12, wherein a temperature of the bonding process is between 100 and 300° C.

14. The manufacturing method of the micro-LED display device according to claim 12, wherein after performing a bonding process, the first bonding support layer fills a space between the first electrode and the second electrode.

15. The manufacturing method of the micro-LED display device according to claim 12, wherein the substrate has a plurality of first circuit layers and a plurality of second circuit layers, and the carrier substrate has a plurality of micro-LEDs.

16. The manufacturing method of the micro-LED display device according to claim 15, wherein in the step of patterning the bonding support material, a plurality of first bonding support layers and a plurality of second bonding support layers are simultaneously formed, and the second bonding support layers are disposed between the micro-LEDs.

17. The manufacturing method of the micro-LED display device according to claim 16, further comprising:
forming a plurality of shielding layers on the second bonding support layers.

18. The manufacturing method of the micro-LED display device according to claim 12, further comprising:
forming an optically clear adhesive on the micro-LED.

19. The manufacturing method of the micro-LED display device according to claim 12, further comprising:
performing a curing process after the bonding process, wherein an adhesive force is formed in a contact surface of the first bonding support layer and the micro-LED and a contact surface of the first bonding support layer and the substrate through the curing process, so that the micro-LED is affixed to the substrate.
